(19) United States
(12) Patent Application Publication
(10) Pub. No.: US 2009/0194155 A1
(43) Pub. Date: Aug. 6, 2009

(54) Front electrode having etched surface for use in photovoltaic device and method of making same

(75) Inventors: Willem den Boer, Brighton, MI (US); Alexey Krasnov, Canton, MI (US); John A. Vanderploeg, Highland, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 12/068,119

(22) Filed: Feb. 1, 2008

(51) Int. Cl. H01L 31/00; C23C 14/34

(52) U.S. Cl. 136/256; 204/192.25

(57) ABSTRACT

Certain example embodiments of this invention relate to a photovoltaic (PV) device including an electrode such as a front electrode/contact, and a method of making the same. In certain example embodiments, the front electrode has a textured (e.g., etched) surface that faces the photovoltaic semiconductor film of the PV device. In certain example embodiments, the front electrode is formed on a flat or substantially flat (non-textured) surface of a glass substrate (e.g., via sputtering), and the surface of the front electrode is textured (e.g., via etching). In completing manufacture of the PV device, the etched surface of the front electrode faces the active semiconductor film of the PV device.

Certain example embodiments of this invention relate to a photovoltaic (PV) device including an electrode such as a front electrode/contact and a method of making the same. In certain example embodiments, the front electrode has a textured (e.g., etched) surface that faces the photovoltaic semiconductor film of the PV device. In certain example embodiments, the front electrode is formed on a flat or substantially flat (non-textured) surface of a glass substrate, and after formation of the front electrode the surface of the front electrode is textured (e.g., via etching). In completing manufacture of the PV device, the etched surface of the front electrode faces the active semiconductor film of the PV device.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon photovoltaic devices, for example, include a front electrode or contact. Typically, the transparent front electrode is made of a pyrolytic transparent conductive oxide (TCO) such as zinc oxide or tin oxide formed on a substrate such as a glass substrate. In many instances, the transparent front electrode is formed of a single layer using a method of chemical pyrolysis where precursors are sprayed onto the glass substrate at approximately 400 to 600 degrees C. Typical pyrolitic fluorine-doped tin oxide TCOs as front electrodes may be about 400 nm thick, which provides for a sheet resistance (Rₛ) of about 15 ohms/square. To achieve high output power, a front electrode having a low sheet resistance and good ohm-contact to the cell top layer, and allowing maximum solar energy in certain desirable ranges into the absorbing semiconductor film, are desired.

It would be desirable to provide a technique and structure for improving the ability of the semiconductor film (or absorber) of the photovoltaic (PV) device to absorb light and thus generate electrical charges.

Certain example embodiments of this invention relate to a photovoltaic (PV) device including an electrode such as a front electrode/contact and a method of making the same. In certain example embodiments, the front electrode has a textured (e.g., etched) surface that faces the photovoltaic semiconductor film of the PV device. The textured surface of the front electrode, facing the semiconductor absorber film, is advantageous in that it increases the amount of incoming radiation or solar energy that is absorbed by the semiconductor film of the PV device. In certain example embodiments, the front electrode is formed on a flat or substantially flat (non-textured) surface of a front glass substrate, and after formation of the front electrode via sputtering or the like, the surface of the front electrode is textured (e.g., via etching). In completing manufacture of the PV device, the textured (e.g., etched) surface of the front electrode faces the active semiconductor film (or absorber) of the PV device.

The use of a front electrode having a textured surface adjacent the semiconductor film (or absorber) is advantageous in that it increases the optical path of incoming solar light within the semiconductor film through light scattering, thereby increasing the chance for photons to be absorbed in the semiconductor film to generate electrical charge.

In certain example embodiments of this invention, the front electrode may be baked (or heat treated) prior to the texturing (e.g., etching). This heat treating helps densify the TCO, thereby permitting a more uniform and predictable texturing to be achieved. Moreover, the more dense film caused by the baking/heating is less permeable to etchant(s) used in etching the TCO, so as to reduce the chance of etchant reaching and damaging other parts of the front electrode. As a result, overall performance of the resulting PV device can be achieved.

In certain example embodiments of this invention, a thin buffer and/or extra dense layer may be provided adjacent the TCO of the front electrode (the TCO is located between the semiconductor film and this thin buffer and/or extra dense layer). The thin buffer and/or extra dense layer(s) render the front electrode less permeable to etchant(s) used in etching the TCO, so as to reduce the chance of etchant reaching and damaging other parts of the front electrode such as a silver based layer thereof. As a result, overall performance of the resulting PV device can be achieved, without permitting the front electrode to be damaged by the etchant(s).

In certain example embodiments of this invention, the front electrode of a photovoltaic device is comprised of a multilayer coating including at least one conductive substantially metallic IR reflecting layer (e.g., based on silver, gold, or the like), and at least one transparent conductive oxide (TCO) layer (e.g., of or including a material such as zinc oxide or the like). In the PV device, the TCO is provided between the semiconductor film and the substantially metallic IR reflecting layer. The surface of the TCO layer may be etched to provide a textured or etched surface facing the semiconductor film.

In certain example instances, the multilayer front electrode coating may include a plurality of TCO layers and/or a plurality of conductive substantially metallic IR reflecting layers arranged in an alternating manner in order to provide for reduced visible light reflections, increased conductivity, increased IR reflection capability, and so forth.

In certain example embodiments of this invention, a multilayer front electrode coating may be designed to realize one or more of the following advantageous features: (a) reduced sheet resistance (Rₛ) and thus increased conductivity and improved overall photovoltaic module output power; (b) increased reflection of infrared (IR) radiation thereby reducing the operating temperature of the photovoltaic module so as to increase module output power; (c) reduced reflection and increased transmission of light in the region(s) of from about 450-1,000 nm, 450-700 nm and/or 450-600 nm which leads to increased photovoltaic module output power; (d) reduced total thickness of the front electrode coating which can reduce fabrication costs and/or time; (e) an improved or enlarged process window in forming the TCO layer(s) because of the reduced impact of the TCO's conductivity on the overall electric properties of the module given the presence of the highly conductive substantially metallic layer(s); and/or (f) increased optical path within the semiconductor film, due to the etched surface of the front electrode, through light scattering thereby increasing the chance for photons to be absorbed in the semiconductor film and through light trapping between the reflective metal back electrode(s) by multiple internal reflections so as to generate additional electrical charge.

In certain example embodiments of this invention, there is provided a photovoltaic device comprising: a front glass substrate; a front electrode provided between the front glass substrate and a semiconductor film of the photovoltaic device, wherein the front electrode comprises a silver-based conductive layer and a transparent conductive oxide (TCO) layer, the TCO layer being provided between the silver-based layer and the semiconductor film of the photovoltaic device; and wherein a major surface of the TCO layer closest to the semiconductor film is etched so as to be textured. In certain example embodiments, after etching the front glass substrate with the etched front electrode thereon has a haze value of from about 10-15% (before the semiconductor and back electrode/substrate are provided adjacent thereto).

In certain example embodiments of this invention, there is provided a photovoltaic device comprising: a front glass substrate; a front electrode provided between the front glass substrate and a semiconductor film of the photovoltaic device, wherein the front electrode comprises a silver-based conductive layer and a transparent conductive oxide (TCO) layer, the TCO layer being provided between the silver-based layer and the semiconductor film of the photovoltaic device; wherein a major surface of the TCO layer closest to the semiconductor film is etched so as to be textured; and wherein the TCO layer is graded with respect to density so that a first portion of the TCO layer closer to the silver-based layer has a higher density than does a second portion of the TCO layer farther from the silver-based layer.

In other example embodiments of this invention, there is provided a photovoltaic device comprising: a front glass substrate; a front electrode provided between the front glass substrate and a semiconductor film of the photovoltaic device, wherein the front electrode comprises, in this order moving away from the front glass substrate, a silver-based conductive layer, a buffer layer comprising metal oxide, and a transparent conductive oxide (TCO) layer, the TCO layer being provided between at least the silver-based layer and the semiconductor film of the photovoltaic device; wherein a major surface of the TCO layer closest to the semiconductor film is etched so as to be textured; and wherein the buffer layer is more resistant to etching than is the TCO layer.

In other example embodiments of this invention, there is provided a mathod of making a photovoltaic device, the method comprising: sputter-depositing a multilayer electrode on a glass substrate at approximately room temperature; heat treating the multilayer electrode at from about 50-400 degrees C. in order to densify at least a transparent conductive oxide (TCO) layer of the electrode; after the heat treating, etching a major exposed surface of the heat treated TCO layer of the electrode in order to form a textured surface; and arranging the textured surface of the TCO layer so as to face a semiconductor film of the photovoltaic device.

In still further example embodiments of this invention, there is provided a method of making a photovoltaic device, the method comprising: sputter-depositing a multilayer electrode, including at least one TCO layer, on a glass substrate at approximately room temperature; etching a surface of the TCO layer to form a textured surface; arranging the textured surface of the TCO layer so as to face a semiconductor film of the photovoltaic device; and adjusting at least one sputtering parameter (e.g., pressure and/or temperature) when sputter-depositing the multilayer electrode so that the TCO layer is deposited so as to have portions of different density, wherein a first portion of the TCO layer closer to the glass substrate has a higher density than does a second portion of the TCO layer farther from the glass substrate.

### BRIEF DESCRIPTION OF THE DRAWINGS

FIG. 1 is a cross sectional view of an example photovoltaic device according to an example embodiment of this invention.

FIG. 2 is a cross sectional view of an example photovoltaic device according to an example embodiment of this invention.

FIG. 3 is a cross sectional view of an example photovoltaic device according to an example embodiment of this invention.

FIG. 4 is a flowchart illustrating certain steps performed in making a photovoltaic device according to an example embodiment of this invention.

FIG. 5 is an intensity versus 2-theta (degrees) graph illustrating that pre-baking of the front electrode prior to etching results in a decrease of the FWHM (full width at half maximum) of the ZnO x-ray diffraction peak at 34.6 degrees (2θ), which corresponds to the <002> orientation of ZnO (this indicates a denser film).

FIG. 6 shows two side-by-side photographs comparing etched surfaces of ZnO TCO, with and without pre-baking, illustrating that the pre-baked TCO (right side of FIG. 6) had a more consistent etched pattern.

FIG. 7 is a flowchart illustrating certain steps performed in making a photovoltaic device according to an example embodiment of this invention.

### DETAILED DESCRIPTION OF EXAMPLE EMBODIMENTS OF THE INVENTION

Referring now more particularly to the figures in which like reference numerals refer to like parts/layers in the several views.

Certain embodiments of this invention relate to a silver-based transparent conductive coating (TCC), used for a front electrode of a photovoltaic device of the like, which has a textured surface. The front electrode may be used, for example, in amorphous silicon (a-Si) based photovoltaic modules. The TCC for the front electrode can be deposited by standard sputtering techniques at room temperature in architectural coaters. The surface of the front electrode is textured by exposure to a mild etchant or the like, which does not substantially change the sheet resistance of the TCC.

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, microcrystalline silicon, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, single or tandem thin-film solar cells, CdS and/or CdTe (including CdS/CdTe) photovoltaic devices, polysilicon and/or microcrystalline Si photovoltaic devices, and the like. This invention may be applicable especially to a-Si single junction and micromorph solar cell modules in certain example embodiments.

Certain example embodiments of this invention relate to a photovoltaic (PV) device including an electrode such as a front electrode/contact 3 and a method of making the same. In certain example embodiments, the front electrode 3 has a textured (e.g., etched) surface 6 that faces the photovoltaic semiconductor film 5 of the PV device. The textured surface 6 of the front electrode 3, facing the semiconductor absorber film 5, is advantageous in that it increases the amount of incoming radiation or solar energy that is absorbed by the semiconductor film 5 of the PV device. In certain example embodiments, the front electrode 3 (e.g., by sputtering at about room temperature) is formed on a flat or substantially flat (non-textured) surface of a front glass substrate 1, and after formation of the front electrode 3 via sputtering at room temperature or the like, the surface of the front electrode is textured (e.g., via etching). In completing manufacture of the PV device, the textured (e.g., etched) surface 6 of the front electrode 3 faces the active semiconductor film (or absorber) 5 of the PV device. The use of a front electrode 3 having a textured surface 6 adjacent the semiconductor film (or absorber) 5 is advantageous in that it increases the optical path of incoming solar light within the semiconductor film 5 through light scattering and light trapping between the front and back electrodes, thereby increasing the chance for photons to be absorbed in the semiconductor film 5 to generate electrical charge.

In certain example embodiments of this invention, the front electrode 3 (or TCC) may be baked (or heat treated) prior to the texturing (e.g., etching). This heat treating helps densify the TCO 4e to be etched, thereby permitting a more uniform and predictable texturing to be achieved. Moreover, the more dense film caused by the baking/heating is less permeable to etchant(s) used in etching the TCO 4e, so as to reduce the chance of etchant(s) reaching and damaging other parts of the front electrode 3. As a result, overall performance of the resulting PV device can be achieved. In certain example embodiments of this invention, a thin buffer 4e′ and/or extra dense layer 4e″ may be provided adjacent the TCO 4e of the front electrode 3. The thin buffer 4e′ and/or extra dense layer(s) 4e″ render the front electrode 3 less permeable to etchant(s) used in etching the TCO 4e, so as to reduce the chance of etchant reaching and damaging other parts of the front electrode such as a silver based layer 4c. As a result, overall performance of the resulting PV device can be achieved, without permitting the front electrode 3 to be undesirably damaged by the etchant(s). In certain example embodiments, the TCO 4e is at least moderately conductive (e.g., <1 kohmcm) to provide a conductive path to the silver 4c for the photocurrent generated in the semiconductor film 5.

In certain example embodiments of this invention, the front electrode 3 of a photovoltaic device is comprised of a multilayer coating including at least one conductive substantially metallic IR reflecting layer (e.g., based on silver, gold, or the like) 4c, and at least one transparent conductive oxide (TCO) layer (e.g., of or including a material such as zinc oxide or the like) 4e. In the PV device, the TCO 4e is provided between the semiconductor film 5 and the substantially metallic IR reflecting layer 4c. In certain example instances, the multilayer front electrode coating may include a plurality of TCO layers and/or a plurality of conductive substantially metallic IR reflecting layers 4c arranged in an alternating manner in order to provide for reduced visible light reflections, increased conductivity, increased IR reflection capability, and so forth.

In certain example embodiments of this invention, a multilayer front electrode coating (e.g., see 3) may be designed to realize one or more of the following advantageous features: (a) reduced sheet resistance (Rₛ) and thus increased conductivity and improved overall photovoltaic module output power; (b) increased reflection of infrared (IR) radiation thereby reducing the operating temperature of the photovoltaic module so as to increase module output power; (c) reduced reflection and increased transmission of light in the region(s) of from about 450-700 nm and/or 450-600 nm which leads to increased photovoltaic module output power; (d) reduced total thickness of the front electrode coating which can reduce fabrication costs and/or time; (e) an improved or enlarged process window in forming the TCO layer(s) because of the reduced impact of the TCO's conductivity on the overall electric properties of the module given the presence of the highly conductive substantially metallic layer(s); and/or (f) increased optical path within the semiconductor film, due to the etched surface 6 of the front electrode 3, through light scattering thereby increasing the chance for photons to be absorbed in the semiconductor film so as to generate additional electrical charge.

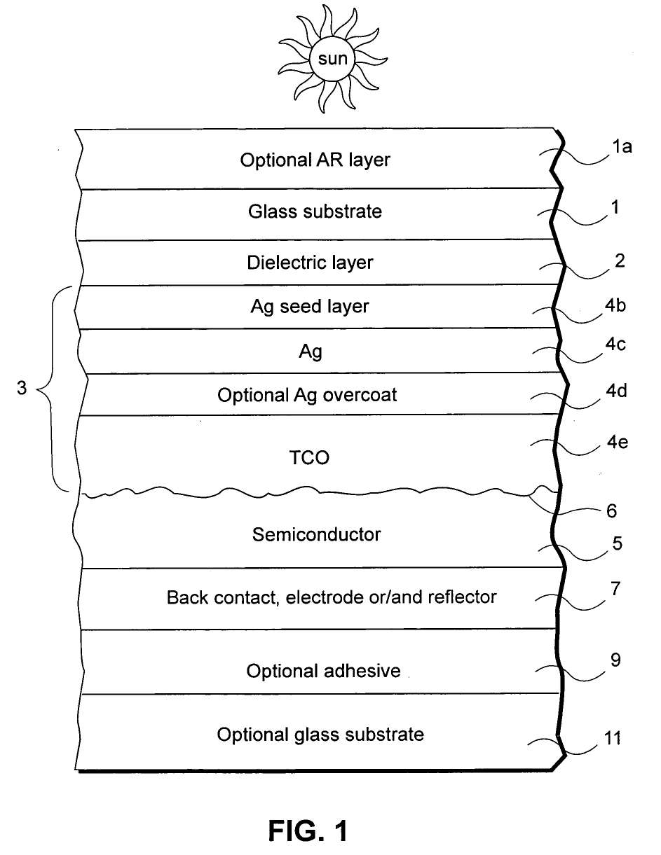

FIG. 1 is a cross sectional view of a photovoltaic device according to an example embodiment of this invention, including a multi-layer front electrode 3. The photovoltaic device includes transparent front glass substrate 1 (other suitable material may also be used for the substrate instead of glass in certain instances), optional dielectric layer(s) 2 (e.g., of or including one or more of silicon oxide, silicon oxynitride, silicon nitride, titanium oxide, niobium oxide, and/or the like) which may function as a sodium barrier for blocking sodium from migrating out of the front glass substrate 1, seed layer 4b (e.g., of or including zinc oxide, zinc aluminum oxide, tin oxide, tin antimony oxide, indium zinc oxide, or the like) which may be a TCO or dielectric in different example embodiments, silver based infrared (IR) reflecting layer 4c, optional overcoat or contact layer 4d (e.g., of or including NiCr, and/or an oxide of Ni and/or Cr, zinc oxide, zinc aluminum oxide, or the like) which may be a TCO, TCO 4e (e.g., of or including zinc oxide, zinc aluminum oxide, tin oxide, tin antimony oxide, zinc tin oxide, indium tin oxide, indium zinc oxide, or the like), semiconductor 5 (e.g., CdS/CdTe, a-Si, or the like), optional back contact, reflector and/or electrode 7 which may be of a TCO or a metal, optional adhesive 9 or adhesive of a material such as ethyl vinyl acetate (EVA) or the like, and optional back glass substrate 11. Semiconductor absorbing film 5 may be made up of one or more layers in different example embodiments, and may be for example pin, pn, pinpin tandem layer stacks, or the like. Of course, other layer(s) which are not shown may also be provided in the PV device of FIG. 1.

Front glass substrate 1 and/or rear superstrate (substrate) 11 may be made of soda-lime-silica based glass in certain example embodiments of this invention; and it may have low iron content and/or an antireflection coating thereon to optimize transmission in certain example instances. The surface (interior surface) of the glass substrate 1 facing the semiconductor 5 and the front electrode 3 is preferably flat or substantially flat/smooth in certain example embodiments of this invention. In other words, the interior surface of the front glass substrate 1 on which the front electrode 3 is formed is non-textured. Thus, layers 2, 4b and 4c (and possibly 4d) are also non-textured so that each of their respective surfaces (both major surfaces of each) are flat or substantially smooth (non-textured) in certain example embodiments of this invention. Moreover, the surface of TCO 4e closest to the front glass substrate 1 is non-textured (or smooth/flat), whereas the opposite surface 6 of the TCO 4e facing the semiconductor 5 is textured (e.g., etched) as discussed herein.

While substrates 1, 11 may be of glass in certain example embodiments of this invention, other materials such as quartz, plastics or the like may instead be used for substrate(s) 1 and/or 11. Moreover, superstrate 11 is optional in certain instances. Glass 1 and/or 11 may or may not be thermally tempered in certain example embodiments of this invention. Optionally, an antireflective (AR) film 1a may be provided on the light incident or exterior surface of the front glass substrate 1 as shown in FIG. 1. Additionally, it will be appreciated that the word “on” as used herein covers both a layer being directly on and indirectly on something, with other layers possibly being located therebetween.

Dielectric layer(s) 2 may be of any substantially transparent material such as a metal oxide and/or nitride which has a refractive index of from about 1.5 to 2.5, more preferably from about 1.6 to 2.5, more preferably from about 1.6 to 2.2, more preferably from about 1.6 to 2.0, and most preferably from about 1.6 to 1.8. However, in certain situations, the dielectric layer 2 may have a refractive index (n) of from about 2.3 to 2.5. Example materials for dielectric layer 2 include silicon oxide, silicon nitride, silicon oxynitride, zinc oxide, tin oxide, titanium oxide (e.g., TiO₂), aluminum oxynitride, aluminum oxide, or mixtures thereof. Dielectric layer(s) 2 functions as a barrier layer in certain example embodiments of this invention, to reduce materials such as sodium from migrating outwardly from the glass substrate 1 and reaching the IR reflecting layer(s) 4c and/or semiconductor 5. Moreover, dielectric layer 2 is material having a refractive index (n) in the range discussed above, in order to reduce visible light reflection and thus increase transmission of visible light (e.g., light from about 450-700 nm and/or 450-600 nm) through the coating and into the semiconductor 5 which leads to increased photovoltaic module output power.

Multilayer front electrode 3 (or TCC), which is provided for purposes of example only and is not intended to be limiting, includes from the glass substrate 1 outwardly (possibly over dielectric layer(s) 2) first transparent conductive oxide (TCO) or dielectric layer 4b (e.g., of or including zinc oxide), first conductive substantially metallic IR reflecting layer 4c (e.g., of or including silver and/or gold), optional overcoat of NiCr, NiCrOₓ or the like, and TCO 4e (e.g., of or including zinc oxide, indium-tin-oxide (ITO), or the like). This multilayer film 3 makes up the front electrode in certain example embodiments of this invention. Of course, it is possible for certain layers of electrode 3 to be removed in certain alternative embodiments of this invention, and it is also possible for additional layers to be provided in the multilayer electrode 3 (e.g., an additional silver based layer 4c may be provided, with a TCO such as zinc oxide or ITO being provided between the two silver based IR reflecting layers 4c). Front electrode 3 may be continuous across all or a substantial portion of front glass substrate 1, or alternatively may be patterned into a desired design (e.g., stripes), in different example embodiments of this invention. Each of layers/films 1-4 is substantially transparent in certain example embodiments of this invention. The surface 6 of TCO 4e facing the semiconductor 5 is etched as discussed herein, in order to provide for improved characteristics of the PV device.

IR reflecting layer(s) 4c may be of or based on any suitable IR reflecting material such as silver, gold, or the like. These materials reflect significant amounts of IR radiation, thereby reducing the amount of IR which reaches the semiconductor film 5. Since IR increases the temperature of the device, the reduction of the amount of IR radiation reaching the semiconductor film 5 is advantageous in that it reduces the operating temperature of the photovoltaic module so as to increase module output power. Moreover, the highly conductive nature of these substantially metallic layer(s) 4c permits the conductivity of the overall front electrode 3 to be increased. In certain example embodiments of this invention, the multilayer electrode 3 has a sheet resistance of less than or equal to about 18 ohms/square, more preferably less than or equal to about 14 ohms/square, and even more preferably less than or equal to about 12 ohms/square. Again, the increased conductivity (same as reduced sheet resistance) increases the overall photovoltaic module output power, by reducing resistive losses in the lateral direction in which current flows to be collected at the edge of cell segments. It is noted that first (and possibly a second) conductive substantially metallic IR reflecting layer 4c (as well as the other layers of the electrode 3) are thin enough so as to be substantially transparent to visible light. In certain example embodiments of this invention, substantially metallic IR reflecting layer 4c is from about 3 to 18 nm thick, more preferably from about 5 to 10 nm thick, and most preferably from about 5 to 8 nm thick. These thicknesses are desirable in that they permit the layer 4c to reflect significant amounts of IR radiation, while at the same time being substantially transparent to visible radiation which is permitted to reach the semiconductor 5 to be transformed by the photovoltaic device into electrical energy. The highly conductive IR reflecting layer 4cs attribute to the overall conductivity of the electrode 3 more than the TCO layer(s); this allows for expansion of the process window(s) of the TCO layer(s) which has a limited window area to achieve both high conductivity and transparency. Seed layer 4b (e.g., of or including ZnO and/or ZnO:Al) is provided for supporting and allowing better crystallinity of the Ag based layer 4c. The overcoat or thin capping layer 4d may be provided over and contacting the silver based layer 4c, for improving the stability of the silver.

TCO layer 4e may be of any suitable TCO material including but not limited to conducive forms of zinc oxide, zinc aluminum oxide, tin oxide, indium-tin-oxide (ITO), indium zinc oxide (which may or may not be doped with silver), or the like. TCO layer 4e provides fro better coupling-in of incoming solar light with the PV device, improves contact properties of the stack, and allows for good mechanical and chemical durability of the coating during shipping and/or processing. This TCO layer 4e is typically substoichiometric so as to render it conductive. For example, layer 4e may be made of material(s) which gives it a resistance of no more than about 10 ohm-cm (more preferably no more than about 1 ohm-cm, and most preferably no more than about 20 mohm-cm). TCO 4e may be doped with other materials such as fluorine, aluminum, antimony or the like in certain example instances, so long as it remains conductive and substantially transparent to visible light. In certain example embodiments of this invention, TCO layer 4e (as deposited or after etching) is from about 20-600 nm thick, more preferably from about 25-500 nm thick, even more preferably from about 25-300 nm thick.

In certain example embodiments of this invention, the photovoltaic device may be made by providing glass substrate 1, and then depositing (e.g., via sputtering or any other suitable technique) multilayer electrode 3 on the substrate 1. Thereafter, the surface of the TCO 4e is etched (e.g., using an etchant(s) such as acetic acid, HF acid, HBr acid, NH₃Fl, or the like—any of which may be mixed with water or the like) to provided etched surface 6, and then the structure including substrate 1 and etched front electrode 3 is coupled with the rest of the device in order to form the photovoltaic device shown in FIG. 1. An example of etching solution that may be used for the etching is a mixture of or including vinegar and water. For example, the semiconductor layer 5 may then be formed over the etched front electrode on substrate 1 so as to be adjacent etched surface 6 of the front electrode 3, and then encapsulated by the substrate 11 via an adhesive 9 such as EVA.

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. The p-type a-Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, hydrogenated microcrystalline silicon, or other suitable material(s) in certain example embodiments of this invention. It is possible for the active region 5 to be of a double-junction or triple-junction type in alternative embodiments of this invention. CdTe may also be used for semiconductor film 5 in alternative embodiments of this invention.

Back contact, reflector and/or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with silver), indium-tin-oxide (ITO), tin oxide, and/or zinc oxide closest to the active region 5, and the back contact may include another conductive and possibly reflective layer of a material such as silver, molybdenum, platinum, steel, iron, niobium, titanium, chromium, bismuth, antimony, or aluminum further from the active region 5 and closer to the superstrate 11. The metal portion may be closer to superstrate 11 compared to the TCO portion of the back contact 7.

The photovoltaic module may be encapsulated or partially covered with an encapsulating material such as encapsulant 9 in certain example embodiments. An example encapsulant or adhesive for layer 9 is EVA or PVB. However, other materials such as Tedlar type plastic, Nuvasil type plastic, Tefzel type plastic or the like may instead be used for layer 9 in different instances.

While the electrode 3 is used as a front electrode in a photovoltaic (PV) device in certain embodiments of this invention described and illustrated herein, it is also possible to use the electrode 3 as another electrode in the context of a photovoltaic device or otherwise.

For purposes of example only, an example of the FIG. 1 embodiment is as follows (note that certain optional layers shown in FIG. 1 are not used in this example). For example, referring to FIG. 1, front glass substrate 1 (e.g., about 3.2 mm thick), dielectric layer 2 (e.g., silicon oxynitride about 20 nm thick possibly followed by dielectric TiOx about 20 nm thick), Ag seed layer 4b (e.g., dielectric or TCO zinc oxide or zinc aluminum oxide about 10 nm thick), IR reflecting layer 4c (silver about 5-8 nm thick), optional overcoat of or including NiCr and/or NiCrOₓ 4d, TCO 4e (e.g., conductive zinc oxide, tin oxide, zinc aluminum oxide, ITO from about 50-250 nm thick, more preferably from about 100-150 nm thick). The TCO 4 is etched to provide textured or etched surface 6. The photovoltaic device of FIG. 1 (or any other embodiment herein) may have a sheet resistance of no greater than about 18 ohms/square, more preferably no grater than about 14 ohms/square, even more preferably no greater than about 12 ohms/square in certain example embodiments of this invention. Moreover, the FIG. 1 embodiment (or any other embodiment herein) may have tailored transmission spectra having more than 80% transmission into the semiconductor 5 in part or all of the wavelength range of from about 450-600 nm and/or 450-700 nm, where AM1.5 may have the strongest intensity and in certain example instances the cell may have the highest or substantially the highest quantum efficiency.

For purposes of example only, another example of the FIG. 1 embodiment is as follows. The photovoltaic device may include: optional antireflective (AR) layer 1a on the light incident side of the front glass substrate 1; first dielectric layer 2 of or including one or more of silicon nitride (e.g., Si₃N₄ or other suitable stoichiometry), silicon oxynitride, silicon oxide (e.g., SiO₂ or other suitable stoichiometry), and/or tin oxide (e.g., SnO₂ or other suitable stoichiometry); seed layer 2 (which may be a dielectric or a TCO) of or including zinc oxide, zinc aluminum oxide, tin oxide, tin antimony oxide, indium zinc oxide, or the like; conductive silver based IR reflecting layer 4c; overcoat or contact layer 4d (which may be a dielectric or conductive) of or including an oxide of Ni and/or Cr, NiCr, Ti, an oxide of Ti, zinc aluminum oxide, or the like; and TCO 4e (e.g., including one or more layers) of or including zinc oxide, zinc aluminum oxide, tin oxide, tin antimony oxide, zinc tin oxide, indium tin oxide, indium zinc oxide, and/or zinc gallium aluminum oxide; semiconductor film 5 of or including one or more layers such as CdS/CdTe, a-Si, or the like; optional back contact/electrode/reflector 7 of aluminum or the like; optional adhesive 9 of or including a polymer such as PVB or EVA; and optional back/rear glass substrate 11. In certain example embodiments of this invention, dielectric layer 2 may be from about 5-40 nm thick, more preferably from about 10-20 nm thick; seed layer 4b may be from about 5-20 nm thick, more preferably from about 5-15 nm thick; silver based layer 4c may be from about 5-20 nm thick, more preferably from about 6-10 nm thick; overcoat layer 4d may be from about 0.2 to 5 nm thick, more preferably from about 0.5 to 2 nm thick; and TCO film 4e may be from about 50-200 nm thick, more preferably from about 75-150 nm thick, and may have a resistivity of no more than about 100 mΩ in certain example instances. Moreover, the surface of glass 1 closest to the sun may be patterned via etching or the like in certain example embodiments of this invention.

The front electrode 3 may be of or include any of the front electrodes described in U.S. Ser. No. 11/984,092, filed Nov. 13, 2007, the entire disclosure of which is hereby incorporated herein by reference.

The efficiency of a-Si PV devices can be increased by up to 20% by texturing the surface of the transparent conductor on which the a-Si semiconductor (e.g., see semiconductor film 5) is deposited. Several methods have been developed to achieve texture. First, deposition of pyrolytic fluorine doped SnO2 may be used to form the front electrode. The surface is textured as deposited when the appropriate process parameters are used. Although commercially successful, this method does not give the highest photovoltaic conversion efficiency, because the feature sizes, shapes and distribution are not optimal. In addition, relatively thick SnO2:F films are needed to obtain the required sheet resistance of about 10 ohms/square. Second, low pressure CVD of ZnO:Al in combination with wet etching or texturing by laser may provide for good performance; however, deposition rates are low and system cleaning is cumbersome with LPCVD. In addition, texturing solely by laser is expensive and has low throughput. Third, ZnO:Al sputtered at 200-300° C. followed by a back etch in 0.5 to 1% HCl may be used; however, sputtering at 300° C. requires non-conventional equipment and throughput is lower when glass needs to be heated and cooled. Fourth, instead of texturing the transparent conductor film, the glass 1 can be etched to obtain a textured glass surface; a conformal front electrode is then coated by sputtering, which leads to surface texture at the top surface of the film, following the texture of the glass substrate. However, with this fourth method it is difficult to achieve cost-effectiveness and high throughput of the coating with the desired submicron feature sizes. In addition, strong etchants are required to texture the glass, and as a result the Ag based layer could be rough and have an increased sheet resistance. Thus, there is a need for a textured front electrode 3, which can be manufactured at high speed using sputtering equipment at approximately room temperature, and which leads to optimal and uniform surface features for high PV conversion efficiency.

In certain example embodiments of this invention, a regular smooth, non-textured, float glass is used as a starting substrate 1. Then, at least the following may be sputter-deposited thereon at room temperature: (a) one or more dielectric layers (2 and/or 4b); (b) a thin transparent metal or metal based layer such as silver (4c); and (c) one or more conductive or moderately conductive (<1 kohm cm) transparent oxides, such as ZnO:Al (4e). This stack, for the front electrode 3, is exposed to a mild etchant such as diluted HCl (hydrochloric acid) or diluted CH3COOH (acetic acid) for several seconds to several minutes. The acid preferentially etches the surface of the TCO 4e to create a surface texture on surface 6 suitable for light trapping in amorphous silicon photovoltaic modules and the like. Preferably the angle of the texture (the average angle at which the peaks and/or valleys of the etched surface are provided) is from about 20-45 degrees (e.g., about 30 degrees) with respect to the horizontal. Moreover, the average surface roughness (RMS roughness—the square root of the arithmetic mean of the squares of the feature height) of etched surface 6 is from about 10-50 nm, more preferably from about 15-40 nm, and most preferably from about 20-30 nm. The peaks/valleys on etched surface 6 have an average depth from about 0.05 to 0.5 μm in certain example embodiments. Haze may be from about 6 to 20%, more preferably from about 10-15%, after the etching in certain example embodiments. Note that the haze is the haze of the front glass substrate coated with the etched TCC (not with the semiconductor on it).

### EXAMPLES 1-3

In Example 1, a film stack SiN/TiOx/ZnO/Ag/NiCr/600 nm ZnO was sputter-deposited on a smooth glass substrate 1 at room temperature (the SiN contacted the front glass substrate 1, and the 600 nm thick ZnO was the TCO 4e), and then immersed in a diluted acid of 0.25% HCl in deionized water. The resulting etched TCC (transparent conductive coating) film for the front electrode 3 had a resulting haze of 16% and a sheet resistance of ˜10 Ω/□. The sheet resistance did not change after etching, indicating the Ag layer 4c was not removed, attacked or adversely impacted by the etching process. This etched front electrode 3 could then be used in a PV device, e.g., as shown in FIG. 1.

In Example 2, an extra 400 nm ZnO:Al was deposited on an Ag based TCC as described in Example 1 but with a 140 nm ZnO:Al layer 4e. The resulting texture has a feature size, shape and distribution suitable to strongly enhance light trapping in the thin film semiconductor of a photovoltaic device with a reflecting back contact.

In Example 3, film stack SiN/TiOx/ZnO/Ag/NiCr/600 nm ZnO was sputter-deposited on a smooth glass substrate 1 at room temperature (the SiN contacted the front glass substrate 1, and the 600 nm thick ZnO was the TCO 4e), and then immersed in a diluted acid of 5% CH3COOH (acetic acid) in deionized water. The film had a resulting haze of 10% and the sheet resistance of about 10 Ω/□. The sheet resistance did not significantly change after etching indicating the Ag layer 4c was not attacked, removed or adversely impacted by the etching process.

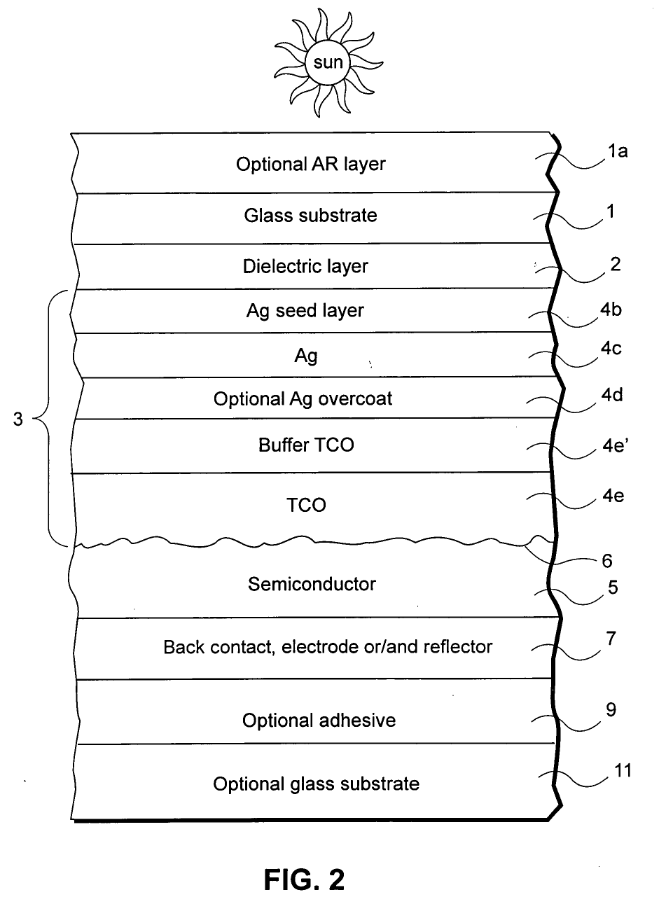

The above examples are non-limiting. Other mild etchants, including acids and base solutions, that do not to attack the silver 4c under the TCO overcoat 4e may also be used. Other metal oxides (ITO, etc.) may also be used as the TCO 4e. When stronger etchants are used, intermediate layer(s) (e.g., tin oxide) (e.g., see buffer layer 4e′ in FIG. 2) as etch stop to protect silver 4c may be provided. For example, tin oxide can be more resistant to acid etching than ZnO and ITO. In other words, in such alternatively, the Ag based layer 4c may be coated first by an etch-resistant thin buffer layer (e.g., tin oxide or other moderately conductive transparent oxide such as layer 4e′ in FIG. 2), followed by the TCO 4e such as ZnO:Al.

In Examples 1-3 above, there is discussed a method of back etching the room-temperature deposited TCO 4e of the TCC 3 using a mild aqueous solution of an acid, such as acetic acid (CH3COOH). ZnAlOx was used as a TCO example for layer 4e. It has been found that, in certain situations, etching of the room-temperature deposited TCO 4e may compromise the performance of the textured coating 3, particularly, its uniformity and lateral conductivity. It appears as if a reason for this is a low density and insufficient crystallinity of TCO materials being deposited at low temperature (room temperature). However, avoiding elevated deposition temperatures is desirable in the context of large-area coating production. Thus, there further exists a need for a method of texturing the TCO 4e of the room-temperature deposited Ag-based TCC stack 3, taking into account possible low density formation of sputter-deposited layers at room temperatures. For instance, certain embodiments of this invention may take advantage of densification of the entire TCO layer 4e, or at least the portion thereof closest to the silver-based layer 4c, in order to improve the performance of the etch-textured coating for a-Si solar cells or the like.

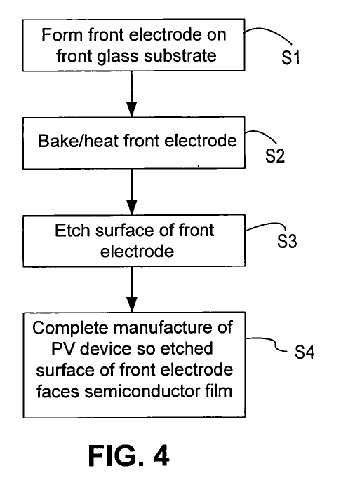

In this respect, FIG. 4 is a flowchart illustrating certain steps taken in making the PV device of any of the FIG. 1-3 embodiments according to an embodiment of this invention. In FIG. 4, the Ag-based front electrode or TCC 3 is formed on the smooth surface of front glass substrate 1 using approximately room-temperature sputtering (step S1). Then, prior to etching, the sputter-deposited Ag-based TCC coating 3 is subjected to baking (or heat treating) (step S2). In certain example embodiments, the heat treating in step S2 may be from about 50 to 400 degrees C., more preferably from about 100 to 400 degrees C. (more preferably from about 150-350 degrees C.), for a time of from about 5 to 60 minutes, more preferably from about 10 to 60 minutes, more preferably from about 20-50 minutes. An example heat treatment is for 30 min at 270 degrees C. Following the heat treatment of step S2, the heat treated (baked) TCC is etched using acetic acid or the like in order to form the textured/etched surface 6 thereof (step S3). Then, the front substrate 1 with the front electrode 3 having etched surface 6 thereof is used in finishing the PV device so that the etched surface 6 faces, and preferably abuts, the semiconductor film 5 of the PV device in the final product (step S4). It is noted that the total thickness of the as-deposited TCO 4e may be from about 100-500 nm, and the post-etch thickness may be from about 20-300 nm for the layer 4e in certain example embodiments of this invention.

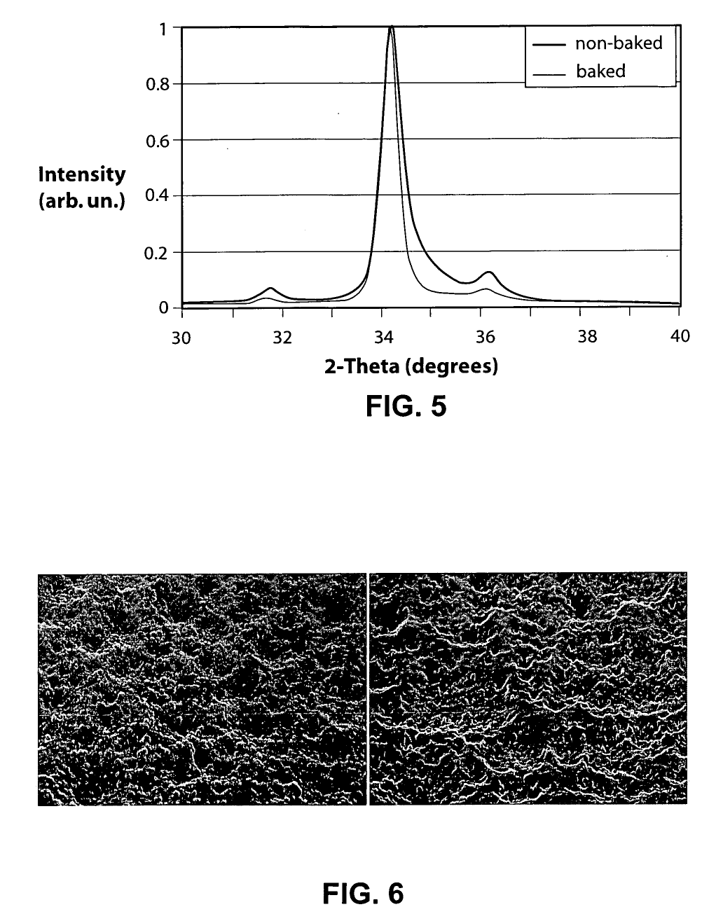

Referring to FIGS. 1 and 4-6, Example 4 was made as follows. A TCC film 3 was sputter-deposited at room temperature on a smooth surface of glass substrate 1, and included a dielectric film 2, a zinc oxide seed layer 4b, silver layer 4c, NiCr or NiCrOₓ layer 4d, and ZnAlOₓ TCO layer 4e. The glass substrate 1 with the TCC film 3 thereon was subjected to baking for thirty minutes at about 270 degrees C. Following the baking, the heat treated (baked) TCC 3 was etched using acetic acid or the like in order to form the textured/etched surface 6. FIG. 5 is an intensity versus 2-theta (degrees) graph illustrating, for this Example, that the baking of the front electrode prior to the etching results in a decrease of the FWHM (full width at half maximum) of the ZnO x-ray diffraction peak at 34.6 degrees (2θ), which corresponds to the <002> orientation of ZnO (this indicates a denser film). Accordingly, the baking was used to densify the film 3 prior to the etching, which resulted in a more consistent etch and a more uniformly etched surface 6 of the TCO 4e.

It is noted that in any embodiment herein, hydrochloric acid may be used as the etchant to form etched surface 6, instead of or in addition to acetic acid or the like. When using acetic acid and/or hydrochloric acid to etch the TCO 4e, the acid concentration may be from about 0.5 to 20%, more preferably from about 1-10%, with an example being about 3.5%, in certain example embodiments of this invention. The etch time may be from about 10-400 seconds, more preferably from about 100-300 seconds, with an example being about 200 seconds, in certain example embodiments of this invention.

FIG. 6 compares the etched surface 6 of Example 4 (right side of FIG. 6), with another similar etched surface where no baking was used (left side of FIG. 6) prior to the etching. In particular, FIG. 6 illustrates two side-by-side photographs comparing etched surfaces of ZnO TCO, with and without pre-baking prior to etching for 200 seconds in 3.5% aqueous solution of acetic acid. The left side of FIG. 6 illustrates a zinc oxide TCO layer that was etched for 200 seconds in 3.5% aqueous solution of acetic acid with no baking prior to the etching. The right side of FIG. 6 illustrates a zinc oxide TCO layer that was etched for 200 seconds in 3.5% aqueous solution of acetic acid, but the etching was performed only after baking the TCO for thirty minutes at about 270 degrees as in Example 4. The left side of FIG. 6 (no baking) shows that when no baking is used prior to etching, the TCO tends to have a number of severe etch craters (e.g., etch pits propagating through the layer) defined therein due to the etching which can lead to uncontrolled light scattering and a non-uniform etched surface (see the several large craters on the left side of FIG. 6). On the other hand, the right side of FIG. 6 (baking in Example 4) shows that when baking is used prior to etching, the TCO after the etching tends to have a more uniformly etched surface 6 with no significant etch craters defined therein. When baking is used before etching, the etch craters, responsible for light scattering, are well controlled and their size and shape can be optimized to most effectively utilize the thickness of the TCO 4e. Moreover, another unexpected advantage is that the haze and sheet resistance non-uniformity of a 10″ by 10″ etched sample improved from 7% to 2.5% when the baking of Example 4 was used prior to the etching. Thus, it will be appreciated that the use of the heat treatment prior to the etching results in a more uniformly etched surface 6 and thus a more controllable light scattering surface and conductive electrode 3 in the final product.

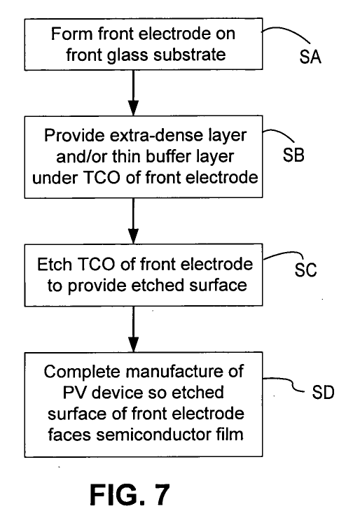

FIG. 7 is a flowchart illustrating certain steps taken in making PV devices according to other example embodiments of this invention. In FIG. 7, the Ag-based front electrode or TCC 3 is formed on the smooth surface of front glass substrate 1 using approximately room-temperature sputtering (step SA). During the deposition of the TCC 3, it is possible to alter the deposition conditions so that the first portion of the TCO layer 4e deposited is more dense than the latter portion of the TCO layer 4e deposited (i.e., the TCO layer 4e is graded with respect to density). See step SB in FIG. 7. Alternatively or in addition, a thin buffer layer 4e′ may be provided between the TCO 4e and the Ag-based layer 4c. Step(s) SB in FIG. 7 recognizes both of these possibilities, which may be used in the alternative or together. Following SA-SB, the TCO layer 4e is etched using acetic acid or the like in order to form the textured/etched surface 6 thereof (step SC). Then, the front substrate 1 with the front electrode 3 having etched surface 6 thereof is used in finishing the PV device so that the etched surface 6 faces, and preferably abuts, the semiconductor film 5 of the PV device in the final product (step SD).

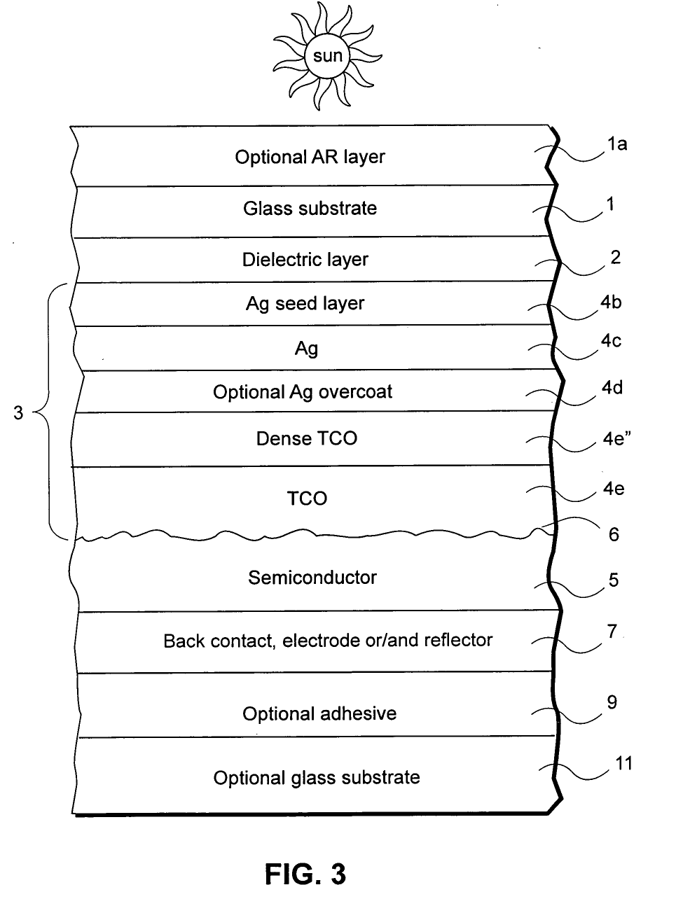

Thus, referring to FIGS. 3 and 7, in another example embodiment of this invention (which may or may not be used with the pre-baking embodiment discussed above, or any other embodiment discussed above), the bottom portion 4e″ of the TCO layer 4e is densified by changing its deposition parameters. As an example, the first layer portion 4e″ in the multi-layer TCO 4e may be sputter-deposited at a lower process pressure, thus providing a denser layer portion 4e″ with lower permeation to the etchant. The process pressure used for layer portion 4e″ may be from about 1 to 4 microBar in certain example embodiments. Then, layer portion 4e of the TCO is sputter-deposited at a higher pressure. The result is a layer including multiple portions, that is density graded so that the portion closest to the Ag based layer 4c is more dense than the portion further from the Ag-based layer 4c. The density grading may be continuous or non-continuous in different example embodiments of this invention. Moreover, the density grading may be step-like or sloped in different example embodiments of this invention. This is advantageous in that it permits etching to be performed mainly of the less dense portion 4e, whereas the more dense portion 4e″ is provided to prevent or reduce the likelihood of etch craters from breaking through the layer and reaching Ag-based layer 4c.

Referring to FIGS. 2 and 7, a thin buffer layer 4e′, such as conductive tin oxide or the like, may be introduced between the capping layer 4d and the TCO 4e to prevent or reduce damage of the Ag-based layer 4c by the acid using during the etching. As an example, undoped tin oxide has a low conductivity when sputter deposited. Thus, if undoped tin oxide is used for buffer layer 4e′, then to provide for sufficient vertical conductivity from the Ag layer 4c to the semiconductor 5, the thickness of the buffer layer 4e′ should be from about 3 to 20 nm. Another alternative is to introduce a donor dopant (such as Sb or the like) into tin oxide in buffer layer 4e′, during the deposition, in order to improve the conductivity of the buffer layer 4e′. When such a dopant is provided in layer 4e′, the conductivity of buffer layer 4e′ improves and the thickness thereof may be increased. When Sb or the like is added to layer 4e′, the Sb concentration may be from about 1-10% by weight, more preferably from about 2-10%, with an example being about 5%.

In certain example embodiments of this invention, referring to FIGS. 1-7 above, the TCC 3 following etching may have a haze of from about 1-30% in the visible, more preferably from about 8-20%, with an example being about 16% in certain example embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A photovoltaic device comprising:
a front glass substrate;
a front electrode provided between the front glass substrate and a semiconductor film of the photovoltaic device, wherein the front electrode comprises a silver-based conductive layer and a transparent conductive oxide (TCO) layer, the TCO layer being provided between the silver-based layer and the semiconductor film of the photovoltaic device;
wherein a major surface of the TCO layer closest to the semiconductor film is etched so as to be textured; and
wherein the TCO layer is graded with respect to density so that a first portion of the TCO layer closer to the silver-based layer has a higher density than does a second portion of the TCO layer farther from the silver-based layer.

2. The photovoltaic device of claim 1, wherein the first and second portions of the TCO layer each comprise zinc oxide.

3. The photovoltaic device of claim 1, wherein the first and second portions of the TCO layer comprise different materials.

4. The photovoltaic device of claim 1, wherein the first and second portions of the TCO layer are of the same material.

5. The photovoltaic device of claim 1, further comprising a layer comprising Ni and/or Cr provided between at least the silver-based layer and the TCO layer.

6. The photovoltaic device of claim 1, wherein the semiconductor film comprises amorphous silicon.

7. The photovoltaic device of claim 1, further comprising a layer comprising zinc oxide between the front glass substrate and the silver-based layer, said layer comprising zinc oxide contacting the silver-based layer.

8. The photovoltaic device of claim 1, wherein the textured surface of the TCO layer has an average RMS roughness value of from about 10-50 nm.

9. The photovoltaic device of claim 1, wherein the textured surface of the TCO layer has an average RMS roughness value of from about 15-40 nm.

10. The photovoltaic device of claim 1, wherein a major surface of the front glass substrate facing the front electrode is smooth and is not textured.

11. A photovoltaic device comprising:
a front glass substrate;
a front electrode provided between the front glass substrate and a semiconductor film of the photovoltaic device, wherein the front electrode comprises, in this order moving away from the front glass substrate, a silver-based conductive layer, a buffer layer comprising metal oxide, and a transparent conductive oxide (TCO) layer, the TCO layer being provided between at least the silver-based layer and the semiconductor film of the photovoltaic device;
wherein a major surface of the TCO layer closest to the semiconductor film is etched so as to be textured; and
wherein the buffer layer is more resistant to etching than is the TCO layer.

12. The photovoltaic device of claim 11, wherein the textured surface of the TCO layer has an average RMS roughness value of from about 10-50 nm.

13. The photovoltaic device of claim 11, wherein the textured surface of the TCO layer has an average RMS roughness value of from about 15-40 nm.

14. The photovoltaic device of claim 11, wherein the buffer layer comprises tin oxide.

15. The photovoltaic device of claim 11, wherein the buffer layer is thinner than the TCO layer.

16. The photovoltaic device of claim 11, wherein the buffer layer comprises tin oxide and the TCO layer comprises zinc oxide.

17. The photovoltaic device of claim 11, further comprising a layer comprising Ni and/or Cr provided between at least the silver-based layer and the buffer layer.

18. The photovoltaic device of claim 11, wherein the semiconductor film comprises amorphous silicon.

19. The photovoltaic device of claim 11, further comprising a layer comprising zinc oxide between the front glass substrate and the silver-based layer, said layer comprising zinc oxide contacting the silver-based layer.

20. The photovoltaic device of claim 11, wherein a major surface of the front glass substrate facing the front electrode is smooth and is not textured.

21. A method of making a photovoltaic device, the method comprising:
sputter-depositing a multilayer electrode on a glass substrate at approximately room temperature;
heat treating the multilayer electrode at from about 50-400 degrees C. in order to densify at least a transparent conductive oxide (TCO) layer of the electrode;
after the heat treating, etching a major exposed surface of the heat treated TCO layer of the electrode in order to form a textured surface; and
arranging the textured surface of the TCO layer so as to face a semiconductor film of the photovoltaic device.

22. The method of claim 19, wherein the TCO comprises zinc oxide.

23. The method of claim 19, wherein the multilayer electrode comprises a silver-based layer and the TCO layer, wherein the TCO layer is closer to the semiconductor film of the photovoltaic device than is the silver-based layer.

24. The method of claim 19, wherein the etching comprises exposing the surface of the TCO layer to one or more of acetic acid and hydrochloric acid.

25. The method of claim 19, wherein the heat treating is performed for from about 10-60 minutes.

26. The method of claim 19, wherein the etching is performed so that the resulting textured surface of the TCO layer has an average RMS roughness value of from about 10-50 nm.

27. The method of claim 19, wherein the etching is performed using a mixture comprising vinegar and water.

28. A method of making a photovoltaic device, the method comprising:
sputter-depositing a multilayer electrode, including at least one TCO layer, on a glass substrate at approximately room temperature;
etching a surface of the TCO layer to form a textured surface;
arranging the textured surface of the TCO layer so as to face a semiconductor film of the photovoltaic device; and
adjusting at least one sputtering parameter when sputter-depositing the multilayer electrode so that the TCO layer is deposited so as to have portions of different density, wherein a first portion of the TCO layer closer to the glass substrate has a higher density than does a second portion of the TCO layer farther from the glass substrate.

29. The method of claim 28, wherein the TCO comprises zinc oxide.

30. The method of claim 28, wherein the multilayer electrode comprises a silver-based layer and the TCO layer, wherein the TCO layer is closer to a semiconductor film of the photovoltaic device than is the silver-based layer.

31. The method of claim 28, wherein the etching comprises exposing the surface of the TCO layer to one or more of acetic acid and hydrochloric acid.

32. The method of claim 28, wherein the etching is performed so that the resulting textured surface of the TCO layer has an average RMS roughness value of from about 10-50 nm.

33. The method of claim 28, further comprising heat treating the multilayer electrode at from about 50-400 degrees C. prior to the etching.

34. The method of claim 28, wherein the sputtering parameter is pressure.

35. The method of claim 28, wherein the etching is performed using a mixture comprising vinegar and water.

36. A photovoltaic device comprising:
a front glass substrate;
a front electrode provided between the front glass substrate and a semiconductor film of the photovoltaic device, wherein the front electrode comprises a silver-based conductive layer and a transparent conductive oxide (TCO) layer, the TCO layer being provided between the silver-based layer and the semiconductor film of the photovoltaic device; and
wherein a major surface of the TCO layer closest to the semiconductor film is etched so as to be textured.

37. The photovoltaic device of claim 36, wherein after etching the front glass substrate with the etched front electrode thereon has a haze value of from about 10-15%.
